(19) United States
(12) Patent Application Publication
(10) Pub. No.: US 2010/0025747 A1
(43) Pub. Date: Feb. 4, 2010

(54) METHOD FOR INITIALIZING FERROELECTRIC MEMORY DEVICE, FERROELECTRIC MEMORY DEVICE, AND ELECTRONIC EQUIPMENT

(75) Inventor: Shinichi FUKADA, Hachioji (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/487,104

(22) Filed: Jun. 18, 2009

(30) Foreign Application Priority Data
Jul. 31, 2008 (JP) 2008-197993

(51) Int. Cl. H01L 29/00; H01L 21/00

(52) U.S. Cl. 257/295; 438/3; 257/E29.001; 257/E21.001

(57) ABSTRACT

A method for initializing a ferroelectric memory device is provided. The method includes the steps of: packaging a ferroelectric memory device having memory cells arranged in an array, each of the memory cells having a ferroelectric film disposed between a lower electrode and an upper electrode; applying a potential between the lower electrode and the upper electrode in an examination step; and after the examination step, applying a first potential to the upper electrode and applying a second voltage higher than the first potential to the lower electrode, and thereafter conducting a heat treatment at a first temperature higher than an operation guarantee temperature.

The entire disclosure of Japanese Patent Application No. 2008-197993, filed Jul. 31, 2008 is expressly incorporated by reference herein.

### BACKGROUND

1. Technical Field

The present invention relates to technologies for initializing ferroelectric memory devices.

2. Related Art

A ferroelectric memory device (FeRAM: Ferroelectric Random Access Memory) is a memory device that uses the property (remnant polarization property) of a ferroelectric film in which the film is polarized by an externally applied electric filed, and the polarization remains even when the external electric field is removed. By changing the direction of electric field to be applied, the direction of polarization of ferroelectrics changes, whereby data can be rewritten.

The ferroelectric film is required to have high film fatigue endurance, high retention property, small imprint phenomenon, and other various properties.

Imprint is a phenomenon in which a polarization caused by application of a pulse voltage in one direction becomes difficult to reverse when a pulse voltage in a reverse direction is applied. Such imprint phenomenon could lead to operation errors.

For example, Japanese Laid-open Patent Application JP-A-9-232532 (Patent Document 1) describes a technology in which an inverse imprint processing is conducted for 14 minutes at 450° C. while impressing a voltage of 12V between electrodes (23, 25), thereby correcting the central slippage in ferroelectric hysteresis.

Also, Japanese Laid-open Patent Application JP-A-2005-148808 (Patent Document 2) describes a technology for preventing influence of imprint by performing, in a step prior to the carding process, a cool down processing, in which writing carried out while reversing data is repeated while the voltage is lowered at fixed intervals.

However, even by conducting the inverse imprint processing after sputtering Pt that becomes the upper electrode in order to address imprint phenomenon, as described in Patent Document 1, imprint phenomenon could occur in later steps, such as, packaging step, examination step and the like. In particular, processing and examination at high temperature may often have to be conducted, the measure described in Patent Document is not sufficient. Also, after sputtering Pt that becomes the upper electrode 25, it is difficult to apply a heat treatment while applying a voltage between the electrodes (23, 25) in a so-called wafer state. Therefore, methods that can reduce the imprint phenomenon with a simple process are desired.

According to the technology described in Patent Document 2, the cool down processing is conducted in advance in order to prevent imprint from occurring in steps to be conducted later, thereby setting data (value) stored in capacitors to a state that is neither “0” or “1.” However, this technology cannot reduce imprint that has already occurred in capacitors.

### SUMMARY

In accordance with an advantage of some aspects of embodiments of the present invention, there is provided a method for initializing a ferroelectric memory device, which is capable of resetting imprint phenomenon of capacitors caused by past thermal history, and reducing effects of imprint phenomenon that may be caused by processing to be conducted later.

(1) In accordance with an embodiment of the invention, a method for initializing a ferroelectric memory device includes the steps of: packaging a ferroelectric memory device having memory cells arranged in an array, each of the memory cells having a ferroelectric film disposed between a lower electrode and an upper electrode; applying a potential between the lower electrode and the upper electrode in an examination step; after conducting the examination step, applying a first potential to the upper electrode and applying a second voltage higher than the first potential to the lower electrode; and thereafter conducting a heat treatment at a first temperature higher than an operation guarantee temperature.

According to the method described above, by imprinting the upper electrode in the positive direction at a temperature higher than an operation guarantee temperature in advance, the upper electrode can be prevented from imprinting in the negative direction later in a use state. It is noted here that the imprinting in the negative direction means that the hysteresis loop shifts to the left (in the negative potential direction) when potentials impressed to the upper electrode are plotted along the axis of abscissas.

For example, the ferroelectric film may be a film formed with crystal grown on the lower electrode. When a film of crystal grown on the lower electrode is used, the upper electrode would likely be imprinted in the negative direction. However, by imprinting the upper electrode in the positive direction, the initial imprint can be corrected.

For example, the first temperature may be higher than an examination temperature in the examination step and a treatment temperature in the packaging step. By this method, even when the upper electrode is imprinted in the negative direction in the examination step or the packaging step, the imprint phenomenon can be reset.

For example, the memory cell may have a MISFET that is connected between the lower electrode and a bit line, and the memory cell is a 1T1C type cell. Also, the memory cell may have MISFETs that are connected between the lower electrodes and bit lines, and the memory cell may be a 2T2C type cell. In this manner, the initializing method described above is applicable to both of 1T1C type and 2T2C type cells.

(2) A ferroelectric memory device in accordance with an embodiment of the invention is a ferroelectric memory device that is initialized by the method for initializing a ferroelectric memory device described above. According to such a structure, the upper electrode is imprinted in the positive direction in advance such that the upper electrode can be prevented from imprinting in the negative direction later in a use state, whereby its device characteristics can be improved. For example, the operation margin (write operation margin, in particular) can be improved. Also, low voltage driving (low voltage writing, in particular) becomes possible.

(3) A ferroelectric device in accordance with an embodiment of the invention includes: first and second bit lines; a 2T2C type memory cell having a first MISFET and a first ferroelectric capacitor connected in series between the first bit line and a plate line, and a second MISFET and a second ferroelectric capacitor connected in series between the second bit line and the plate line; and an initialization circuit for initializing the memory cell, wherein each of the first and second ferroelectric capacitors has a ferroelectric film disposed between a lower electrode and an upper electrode, and the initialization circuit applies, based on an initialization signal, a first potential to the upper electrode of each of the first and second ferroelectric capacitors, and a second potential higher than the first potential to the lower electrode of each of the first and second ferroelectric capacitors.

According to such a structure, even in the case of a 2T2C type memory cell, the upper electrodes of both of the cells can be imprinted in the positive direction.

Preferably, after an operation of the initialization circuit, a heat treatment may be conducted at a temperature higher than an operation guarantee temperature. In this manner, the upper electrode is imprinted in the positive direction at a temperature higher than the operation guarantee temperature in advance, whereby the upper electrode can be prevented from imprinting in the negative direction later in a use state.

(4) Electronic equipment in accordance with an embodiment of the invention includes the ferroelectric memory device described above. According to such a structure, characteristics of the electric equipment can be improved. It is noted that the electronic equipment refers to equipment in general that is equipped with a ferroelectric memory device in accordance with the embodiment and performs predetermined functions. Without any particular limitation to its structure, the electronic equipment may include any and all devices that require a memory device, such as, for example, computer devices in general, cellular phones, PHS, PDA, electronic note books, IC cards and the like equipped with the ferroelectric memory device described above.

### BRIEF DESCRIPTION OF THE DRAWINGS

FIG. 1 is a block diagram of the structure of a ferroelectric memory device in accordance with an embodiment of the invention.

FIG. 2 is a cross-sectional view of a primary section of a stacked type ferroelectric memory cell.

FIG. 3 is a graph showing operations of the ferroelectric memory cell.

FIGS. 4-4D are diagrams and a graph showing operations of the ferroelectric memory cell.

FIG. 5 is a graph for describing imprint phenomenon.

FIG. 6 is a cross-sectional view indicating a method for initializing a ferroelectric memory device in accordance with Embodiment 1.

FIG. 7 is a graph showing hysteresis characteristics (Graph a1) obtained when a heat treatment is conducted at 200° C. for four hours, after data “1” has been written.

FIG. 8 is a graph showing, as a comparison example, hysteresis characteristics (Graph a2) obtained when a heat treatment is conducted at 200° C. for four hours, after a reverse imprint processing has been conducted, in other words, data “0” has been written.

FIGS. 9A and 9B are graphs showing coercive electric fields (+Vc, −Vc) obtained after fatigue tests when an imprint processing in accordance with the present embodiment is conducted [Graph A], the imprint processing is not conducted [Graph B], and a reverse imprint processing is conducted [Graph C], respectively.

FIG. 10 is a block diagram of a ferroelectric memory device in accordance with Embodiment 2 of the invention.

### DESCRIPTION OF EXEMPLARY EMBODIMENTS

Preferred embodiments of the invention are described in detail below with reference to the accompanying drawings. It is noted that components having the same function shall be appended with the same or related reference numbers, and their description shall not be repeated.

### Embodiment 1

Structure and Operation of Ferroelectric Memory Device

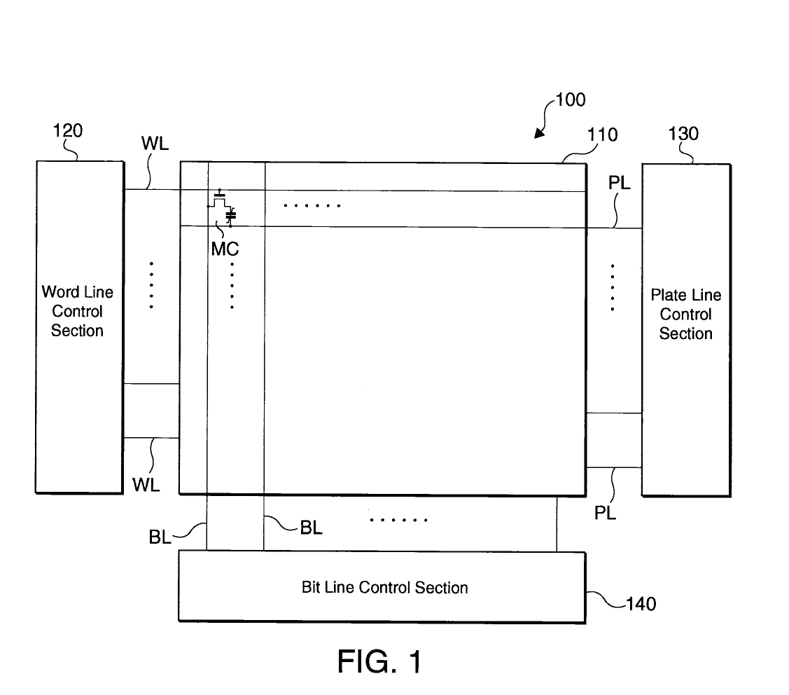

FIG. 1 is a block diagram of the structure of a ferroelectric memory device in accordance with an embodiment of the invention. As illustrated, the ferroelectric memory device 100 includes a memory cell array 110, and a peripheral circuit section (120, 130, 140, etc.). The memory cell array 110 is composed of a plurality of memory cells MC arranged in an array configuration, wherein each of the memory cells MC is disposed at an intersection between a word line WL and a bit line BL. In this embodiment, 1T1C cells are exemplified. In this case, each data is stored by a transistor and a ferroelectric capacitor connected in series between the bit line BL and the plate line PL. Also, a word line control section 120 and a plate line control section 130 which compose the peripheral circuit section control voltages on a plurality of word lines and a plurality of plate lines PL. Controlled by these circuits, data stored in the memory cells are read out to plural ones of the bit lines BL, or externally supplied data are written to the memory cells MC through the bit lines BL. These readout operations and write operations are performed by a bit line control section 140.

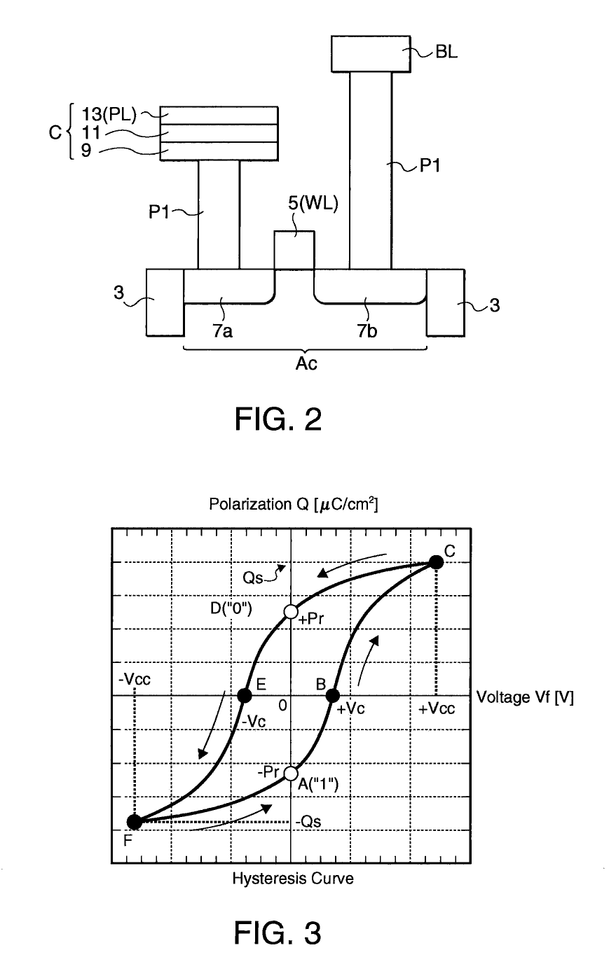

FIG. 2 is a cross-sectional view of a primary section of a stacked type ferroelectric memory cell. As illustrated, a transistor is formed in a primary surface of an element region Ac of the semiconductor substrate that is defined by dielectric layers 3. The transistor includes a gate electrode 5 (word line WL) disposed on the element region Ac through a gate dielectric film (not shown), and source and drain regions 7a, 7b formed on both sides of the gate electrode 5. A lower electrode 9 of the ferroelectric capacitor C is connected through a plug P1 to one of the source and drain regions 7a, and an upper electrode 13 is disposed over the lower electrode 9 through a ferroelectric film 11. The upper electrode 13 may serve as the plate line PL, or may be connected to the plate line PL. On the other hand, the other of the source and drain regions 7b is connected to the bit line BL through another plug P1. In this manner, in the stacked type ferroelectric memory cell, the upper electrode 13 serves as the plate line PL.

For example, the ferroelectric capacitor C is formed in the following manner. A lower electrode 9 composed of a conductive film, such as, for example, a platinum (Pt) film is deposited by a sputtering method or the like on a dielectric film and a plug P1. Then, as a ferroelectric film 11 on the lower electrode 9, for example, a PZT (lead titanate zirconate: Pb(ZrₓTi₁₋ₓ)O₃) film is formed. The ferroelectric film may be formed through coating a solution (a source material solution) in which organometallic compounds containing constituent metals of PZT (Pb, Zr, Ti) are dissolved in a solvent on the substrate by a spin coat method or the like, and then applying heat treatment (drying, degreasing, sintering) to the coated layer, thereby growing crystal with the lower electrode 9 as an orientation film. Then, an upper electrode 13 composed of a conductive film is deposited on the ferroelectric film 11 by a sputtering method or the like, and the deposited layers are patterned. As the ferroelectric film 11, a film of barium titanate (BaTiO₃) or the like may be used, other than the PZT film.

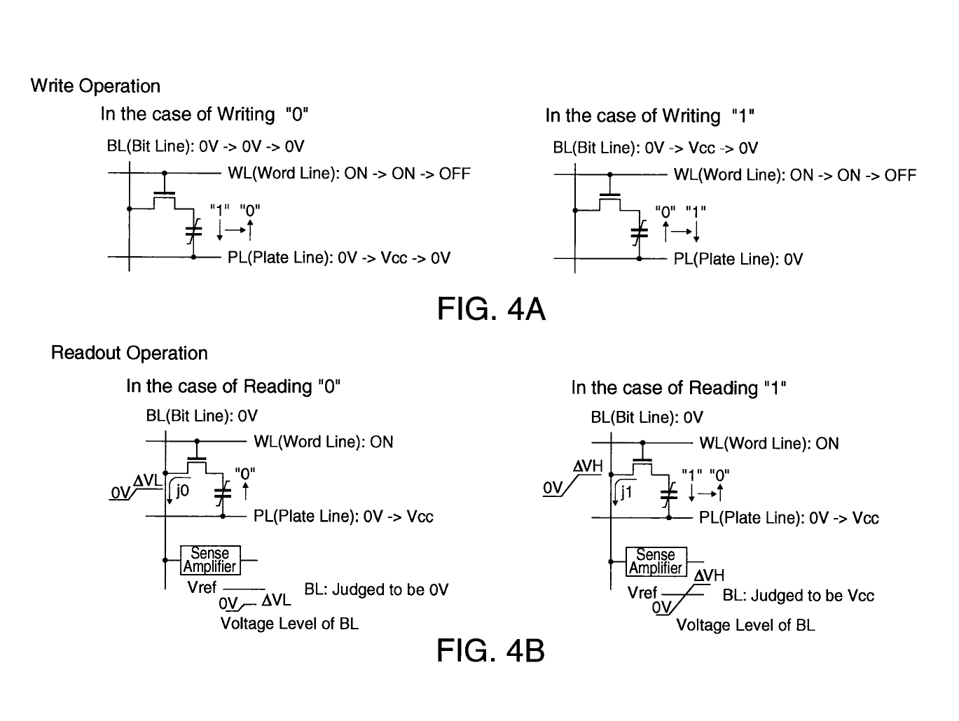

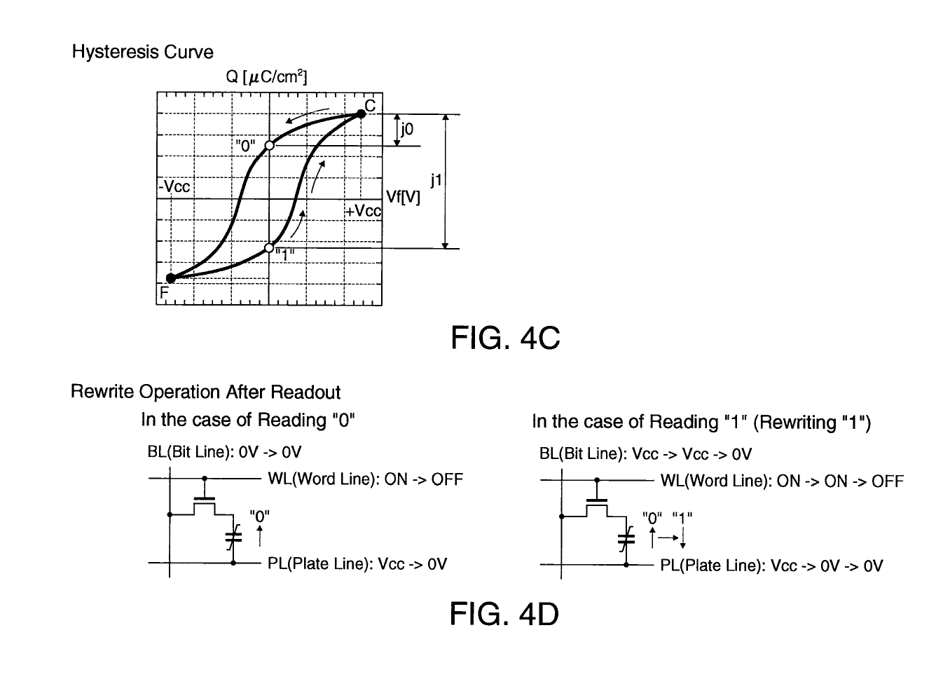

FIG. 3 and FIGS. 4-4D are graphs and diagrams showing operations of the ferroelectric memory. Referring to these figures, operations of the ferroelectric memory are described below.

FIG. 3 shows a hysteresis curve that presents a polarized state with the remnant polarization Q being +Pr or −Pr, at a voltage Vf=0V.

When the voltage Vf is changed from 0V→+Vcc→0V, the polarized state changes from Point A→(Point B)→Point C→Point D. On the other hand, when the voltage is changed from 0V →Vcc→0V, the polarized state changes from Point D→(Point E)→Point F→Point A. Here, Vcc is a driving potential (power supply potential). The polarization at Point C and Point F is Qs and −Qs, which is referred to as saturated polarization, respectively. Also, the voltage (+Vc, −Vc) at Point B and Point E at which polarization becomes 0 is referred to as coercive electric field. Also, the two polarized states may be corresponded to “0” and “1,” and the upward polarization (+Pr) is defined as “0” and the downward polarization (−Pr) is defined as “1.”

As shown in FIG. 4A, for writing data “1” or “0” to the memory cell, the voltage +Vcc or −Vcc is applied between the two electrodes of the ferroelectric capacitor. In other words, for writing data “0” to the memory cell, the word line WL is placed in a selected state (by turning on the transistor), while the potential 0V is applied to the bit line BL, and the potential +Vcc to the plate line. For writing data “1” to the memory cell, the word line WL is placed in a selected state (by turning on the transistor), while the potential +Vcc is applied to the bit line BL, and the potential 0V to the plate line. The data that has been written is retained even when the word line WL becomes to be non-selected (when the transistor is turned off).

As shown in FIG. 4B, for reading out data “1” or “0” from the memory cell, the bit line BL is precharged to 0V before the word line WL is selected, and then the potential +Vcc is applied to the plate line PL. When the memory cell retains data “0,” the potential on the bit line BL slightly rises (+Δ VL) by a relatively small charge shift (j0) without polarization reversion. When the memory cell retains data “1,” a large charge shift (j1) occurs by polarization reversion, and the potential on the bit line BL greatly rises (+Δ VH). The amounts of charge shift (j0, j1) are shown in FIG. 4C. For example, a readout operation is conducted by comparing and amplifying the potential on the bit line BL and a reference potential (Vref) that is located in between.

Next, referring to FIG. 4D, data rewriting is described. In the readout operation to read out data “1” as described above, the data is destroyed by polarization reversion, such that the memory cell has a state in which data “0” is stored (see FIG. 4C). Therefore, it is necessary to write data “1” again. In other words, after the readout operation to read out data “1,” the bit line BL is set to Vcc and the plate line PL is set to 0V, whereby data “1” is rewritten. It is noted that the readout operation to read out data “0” described above does not need rewriting.

Imprint Phenomenon

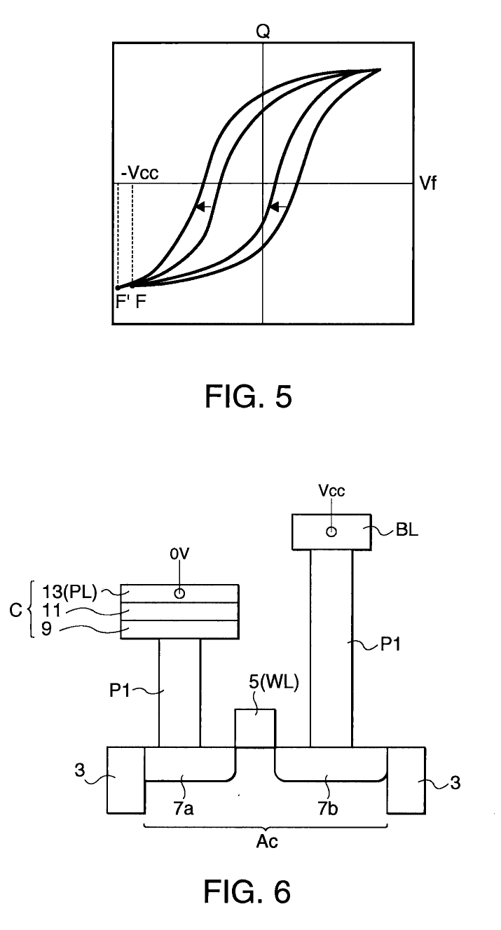

FIG. 5 is a graph for describing imprint phenomenon. As shown in FIG. 5, if the hysteresis curve shifts, for example, to the left, Point F would shift to a point F^{v}, and writing cannot be done with the potential of −Vcc (a potential difference of Vcc). When such imprint phenomenon occurs, the write margin reduces. Moreover, in consideration of such imprint in advance, driving (writing) at a higher potential needs to be set.

In contrast to the above, in accordance with the present embodiment, effects of imprint can be reduced, as described below in detail.

FIG. 6 is a cross-sectional view indicating a method for initializing a ferroelectric memory device in accordance with an embodiment of the invention. The memory device is in a state in which wafer processing has been completed, packaging has been completed, and examination step has been completed, in other words, in a pre-shipping state.

As shown in FIG. 6, in the present embodiment, after selecting the word line WL, and applying 0V to the upper electrode 13 (PL), and Vcc to the bit line BL, the memory cell is exposed to a high temperature atmosphere. In other words, in a state in which data “1” is written to the memory cell, a heat treatment is applied thereto. The imprint processing is conducted in this manner to initialize data.

The temperature described above (processing temperature, imprint temperature) is higher than temperatures in steps prior to the imprint processing, for example, the wafer processing, the packaging step and the examination step. Also, the temperature described above is higher than the usage guarantee temperature of the products.

In this manner, by intentionally imprinting memory cells at a higher temperature than past thermal history, imprint caused by the past thermal history can be reset. Also, by intentionally imprinting memory cells at a higher temperature than the operation guarantee temperature, it is possible to reduce influence of imprint in the reverse direction in a use state.

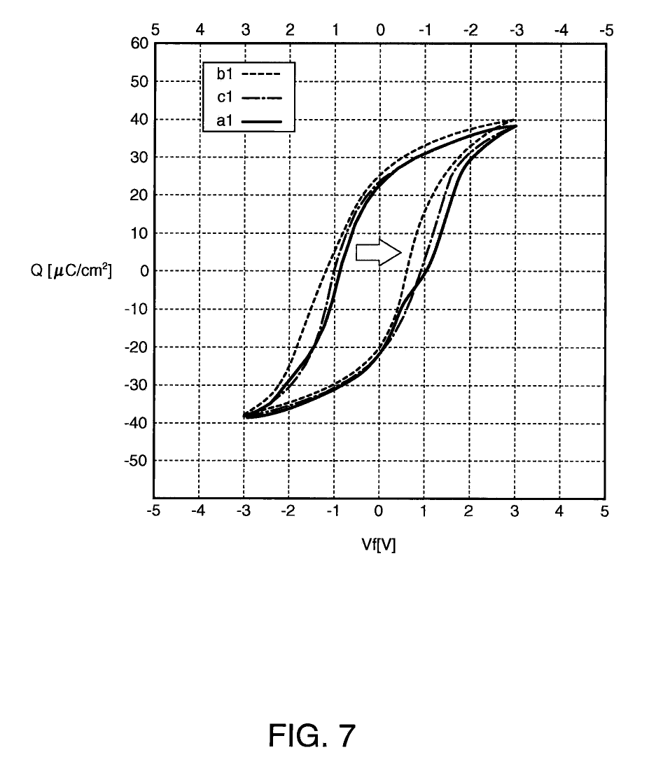

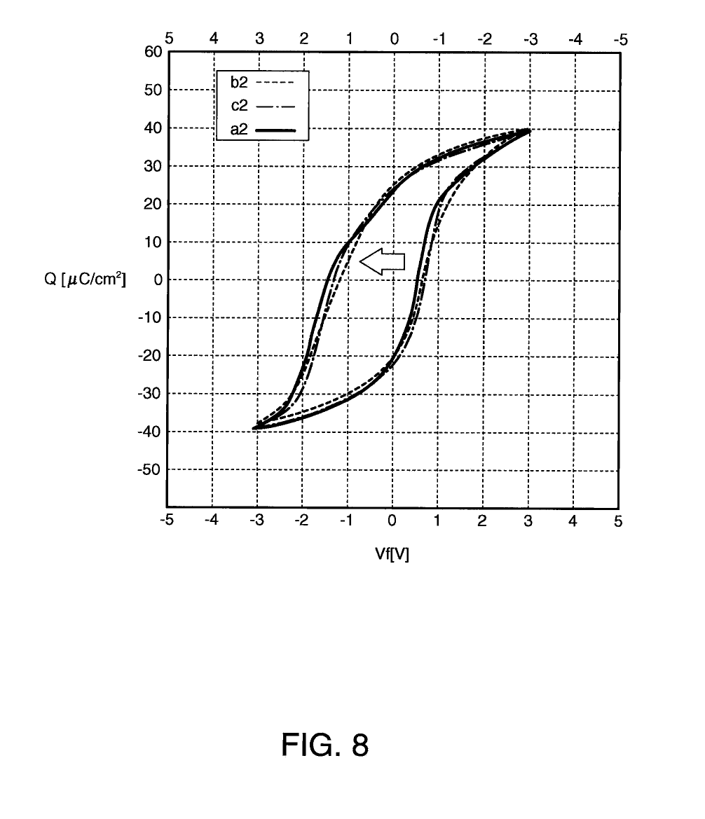

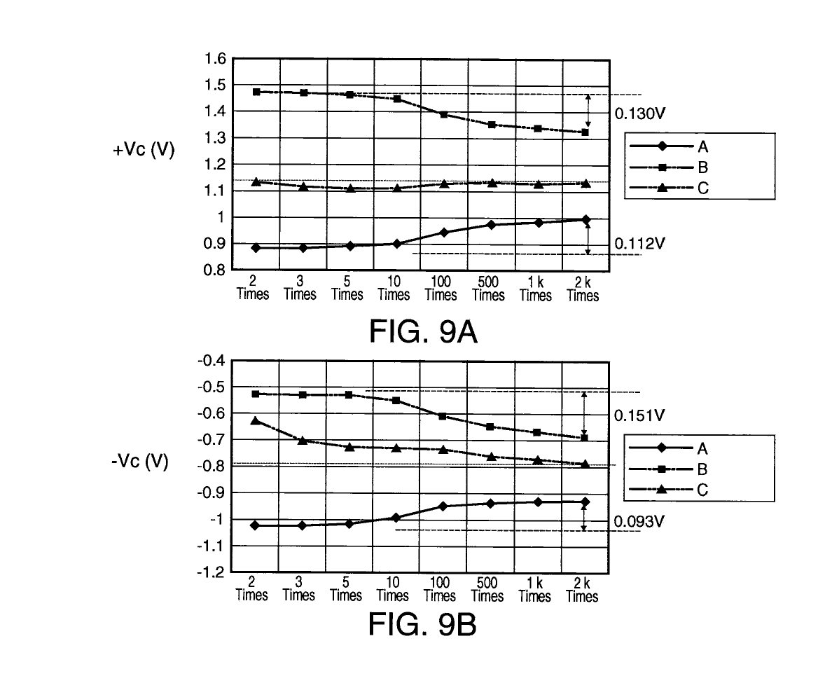

FIG. 7 is a graph showing hysteresis characteristics (Graph a1) obtained when a heat treatment was conducted at 200° C. for four hours, after writing data “1”. Graph b1 indicates a hysteresis characteristic when the above-described processing was not conducted. Graph c1 indicates a hysteresis characteristic after a fatigue test was conducted. In the fatigue test, sweeping at +3V/−3V was conducted 2000 times. FIG. 8 is a graph showing, as a comparison example, hysteresis characteristics (graph a2) obtained when a heat treatment was conducted at 200° C. for four hours, after conducting a reverse imprint processing, in other words, after writing data “0.” Graph b2 indicates a hysteresis when a reverse imprint processing was not conducted. Graph c2 indicates a hysteresis characteristic after a fatigue test was conducted. FIGS. 9A and 9B are graphs showing coercive electric fields (+Vc, −Vc) obtained after fatigue tests, when an imprint processing in accordance with the present embodiment was conducted [Graph A], the imprint processing was not conducted [Graph B], and a reverse imprint processing was conducted [Graph C], respectively, respectively. The axis of ordinates indicates coercive electric field (V), and the axis of abscissas indicates the number of sweeping (times). It is noted that k indicates 1000 times. Also, in FIG. 7 and FIG. 8, Vf is a potential to be applied to the upper electrode (PL), in other words, a relative potential with respect to the lower electrode (BL). It is noted that potentials applied to the lower electrode (BL) are indicated at an upper side of the figure.

As indicated by Graph a1 (solid line) in FIG. 7, when the imprint processing in accordance with the present embodiment was conducted, a good hysteresis characteristic with coercive electric field having good symmetry was obtained. It is clear from the shape of Graph b1 (broken line) that the ordinary device in which imprint processing was not conducted, the hysteresis (coercive electric field) has a tendency to shift to the left. This is believed to have occurred because, for example, the ferroelectric film was formed by growing crystal from the side of the lower electrode, and thus the characteristics of the ferroelectric film are not symmetrical in the up-down direction between the electrodes. In this manner, in stacked type memory cells (ferroelectric capacitors), the hysteresis loop (coercive electric field) tends to shift to the left, but the shift can be corrected by conducting the imprint processing.

Furthermore, as described above, even when a high temperature test has been conducted in the examination step, imprint caused by the test can be reset. The examination step may include a variety of examinations, such as, for example, an all-bit test for judging defects of the device. In this test, predetermined potentials are applied to bit lines BL, word lines WL and plate lines PL, and whether desired readout and writing operations are executed are judged. Also, in order to swiftly conduct the test, the test may often be conducted in a high temperature atmosphere.

Also, in a multilayer wiring formation step after forming ferroelectric capacitors, a heat treatment may be conducted at temperatures near the Curie temperature. Also, in a ceramic package sealing step, the devices are exposed to an atmosphere of about 250° C. Although such a high temperature treatment may cause polarization of ferroelectric films to disappear or reduce, imprint may be caused. Furthermore, at the all-bit test, while potentials are applied to ferroelectric capacitors, thermal load would often be added thereto, which would likely generate imprint.

For example, it is clear from Graph a2 shown in FIG. 8 that, when a heat treatment is conducted at 200° C. for four hours, after data “0” has been written, the hysteresis (coercive electric field) shifts to the left. Also, when an inverse imprint processing is performed, the amount of imprint (the amount of shift) generally tends to become greater, and the operation margin (write margin, in particular) becomes smaller.

In contrast, by the imprint processing in accordance with the present embodiment, the inverse imprint can be reset. Also, imprint is caused in a direction in which the amount of shift becomes smaller, which would cause less influence to write and readout operations.

Moreover, as indicated by Graph a1 (solid line) of FIG. 7, in the imprint processing in accordance with the present embodiment, the hysteresis (coercive electric field) is shifted to the right. In other words, imprint is caused in the positive direction with respect to the voltage applied to the upper electrode, whereby the imprint is caused in a direction in which writing (BL=Vcc, PL=0) can be readily made. It is noted that the imprint in the positive direction means that the hysteresis loop shifts to the right (positive potential direction) when the potential to be applied to the upper electrode is plotted along the axis of abscissas.

Accordingly, writing at low potentials becomes possible, and the write margin can be improved. Conversely, the imprint processing causes imprint in a direction that makes reading (BL=0, PL=Vcc) more difficult, but has fewer impact as the amount of imprint (the amount of shift) is small as described above. Also, for improvement in the readout margin, a full range of circuit designs, such as, use of a bit line ground sensing method and the like, is available. By using one of such circuits, the readout margin can be improved.

In addition, as it is clear from Graph c1 (dot-and-dash line) in FIG. 7 and Graph A in FIGS. 9A and 9B, after conducting the imprint processing in accordance with the present embodiment, the hysteresis characteristic shifts to the left due to the fatigue test. However, the initial hysteresis has been shifted to the right, such that a reduction in the operation margin (write margin) can be suppressed. Also, as it is clear from Graphs A and C in FIGS. 9A and 9B, the hysteresis characteristic shifts to the left due to the fatigue test, but does not return to the hysteresis obtained when the above-described processing was not conducted, whereby favorable characteristics could be maintained.

From the result of the fatigue tests, it is understood that, by conducting the imprint processing in accordance with the present embodiment, the operation margin can be secured even when imprint in a reverse direction occurs in an actual use state after shipment.

In this manner, in accordance with the present embodiment, by conducting, in advance at the time of shipping, the imprint processing in a specified direction which causes a small amount of imprint, the operation margin can be secured even when imprint occurs in a reverse direction in a use state. Also, imprint phenomenon originated from past thermal history and methods for manufacturing capacitors can be reset to a state with good characters.

It is noted that, in accordance with the present embodiment, the imprint processing may be conducted before shipping (after the examination step). However, even when reverse imprint is later caused (in other words, writing reverse data and conducting a heat treatment), if the temperature of the heat treatment is lower than the imprint temperature in accordance with the present embodiment, the effect provided by the present embodiment would not completely disappear. Therefore, after the imprint processing in accordance with the present embodiment, relatively low temperature processing including the examination step can be conducted.

### Embodiment 2

The embodiment 1 is described above, using a 1T1C type memory cell as an example. However, the invention is also applicable to 2T2C type memory cells.

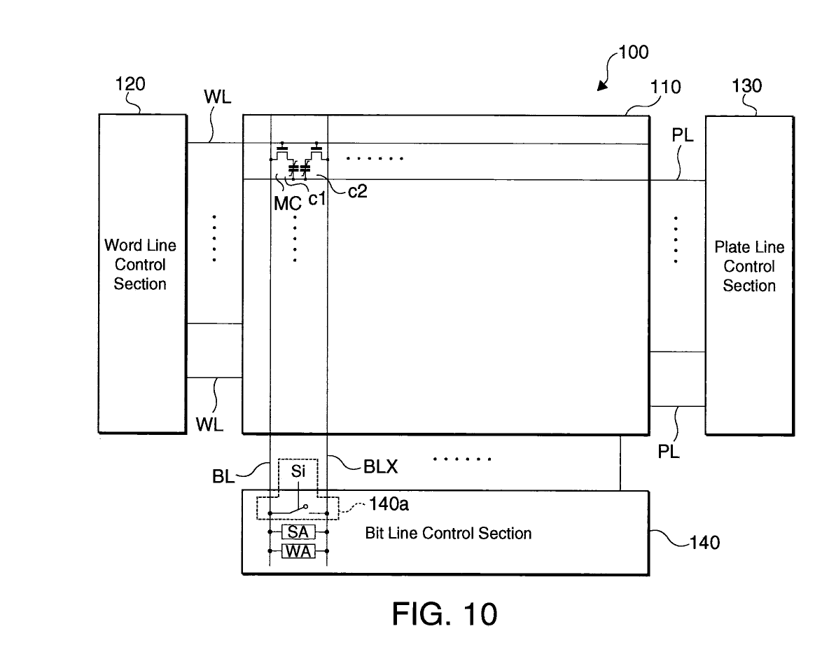

FIG. 10 is a block diagram of a ferroelectric memory device in accordance with another embodiment of the invention. As shown in FIG. 10, in the case of a 2T2C type device, each data is stored by two transistors and two ferroelectric capacitors C1 and C2 respectively connected to bit lines BL and BLX.

At the time of writing, complementary data are written to the two ferroelectric capacitors C1 and C2 by a write amplifier WA. At the time of reading out, charges read out from those capacitors are compared and amplified by a sense amplifier SA, thereby judging whether the ferroelectric capacitors C1, C2 stored data “1” and “0” or stored data “0” and “1”. It is noted that, other than writing complementary data to the two ferroelectric capacitors C1 and C2 and reading from them, the structure and operations of the memory cell of the embodiment 2 are similar to those of the 1T1C type memory cell (FIG. 1), and therefore their detailed description is omitted.

In this manner, in the case of a 2T2C type memory cell, mutually complementary data are written, such that data “1” and “1” would not be written to the two ferroelectric capacitors C1 and C2.

Accordingly, in the present embodiment, an initialization circuit 140a is provided, as shown in FIG. 9, such that data “1” and “1” can be written to the two ferroelectric capacitors C1 and C2, respectively. For example, the initialization circuit is turned on based on an initialization signal Si to set the bit lines BL and BLX to the same potential, thereby writing data “1” and “1” to the two ferroelectric capacitors C1 and C2, respectively.

More specifically, 0V is applied to the upper electrodes (plate line PL) of the two ferroelectric capacitors C1 and C2, and Vcc to the lower electrodes (bit line BL).

It is noted that the initialization circuit 140a is not limited to the structure described above, and a variety of applications and modifications can be made for achieving the operations described above.

In this manner, by writing data “1” and “1” to the two ferroelectric capacitors C1 and C2 by the initialization circuit 140a, and conducting the heat treatment, effects similar to those of the embodiment 1 can be obtained.

It is noted that the embodiment examples and application examples described with reference to the embodiments of the invention may be combined depending on usages, modified or improved for their use, and the invention is not limited to the descriptions of the embodiments presented herein.

What is claimed is:

1. A method for initializing a ferroelectric memory device, the method comprising:
packaging a ferroelectric memory device having memory cells arranged in an array, each of the memory cells having a ferroelectric film disposed between a lower electrode and an upper electrode;
applying a potential between the lower electrode and the upper electrode in an examination step; and
after the examination step, applying a first potential to the upper electrode and applying a second voltage higher than the first potential to the lower electrode, and thereafter conducting a heat treatment at a first temperature higher than an operation guarantee temperature.

2. A method for initializing a ferroelectric memory device according to claim 1, wherein the ferroelectric film is a film formed with crystal grown on the lower electrode.

3. A method for initializing a ferroelectric memory device according to claim 1, wherein the first temperature is higher than an examination temperature in the examination step and a processing temperature in the packaging step.

4. A method for initializing a ferroelectric memory device according to claim 1, wherein the memory cell has a MISFET that is connected between the lower electrode and a bit line, and the memory cell is a 1T1C type cell.

5. A method for initializing a ferroelectric memory device according to claim 1, wherein the memory cell has MISFETs that are connected between the lower electrodes and bit lines, and the memory cell is a 2T2C type cell.

6. A ferroelectric memory device initialized by the method for initializing a ferroelectric memory device according to claim 1.

7. A ferroelectric memory device comprising:
first and second bit lines;
a 2T2C type memory cell having a first MISFET and a first ferroelectric capacitor connected in series between the first bit line and a plate line, and a second MISFET and a second ferroelectric capacitor connected in series between the second bit line and the plate line; and
an initialization circuit for initializing the memory cells,
wherein each of the first and second ferroelectric capacitors has a ferroelectric film disposed between a lower electrode and an upper electrode, and the initialization circuit applies, based on an initialization signal, a first potential to the upper electrode of each of the first and second ferroelectric capacitors, and a second potential higher than the first potential to the lower electrode of each of the first and second ferroelectric capacitors.

8. A ferroelectric memory device according to claim 7, wherein, after an operation of the initialization circuit, a heat treatment is conducted at a temperature higher than an operation guarantee temperature.

9. An electronic equipment comprising the ferroelectric memory device recited in claim 6.
